(19) United States
(12) Patent Application Publication
(10) Pub. No.: US 2015/0332923 A1
(43) Pub. Date: Nov. 19, 2015

(54) LASER ANNEALING APPARATUS AND LASER ANNEALING METHOD

(71) Applicant: THE JAPAN STEEL WORKS, LTD., Tokyo (JP)

(72) Inventors: Toshio KUDO, Kanagawa (JP); Naoyuki KOBAYASHI, Kanagawa (JP); Kazuya SANO, Tokyo (JP); Toshiaki SEINO, Kanagawa (JP); Mitsuhiro TOYODA, Kanagawa (JP)

(73) Assignee: THE JAPAN STEEL WORKS, LTD., Tokyo (JP)

(21) Appl. No.: 14/725,129

(22) Filed: May 29, 2015

Related U.S. Application Data
(62) Division of application No. 13/512,653, filed on May 30, 2012.

(30) Foreign Application Priority Data
Nov. 30, 2009 (JP) 2009-272644

(51) Int. Cl. H01L 21/268; H01L 29/66; H01L 21/324; H01L 21/263

(52) U.S. Cl. CPC H01L 21/268; H01L 21/2636; H01L 29/66325; H01L 21/324

(57) ABSTRACT

The present invention provides an efficient heat treatment such as activation treatment of impurities on a substrate such as a thick silicon wafer with large heat capacity by laser annealing.

Provided is a laser annealing apparatus 1 for heat-treating a surface of a substrate 30 comprising: a pulse oscillation laser source 10 which generates a pulse laser with gentle rise time and long pulse width; a continuous wave laser source 20 which generates a near-infrared laser for assisting annealing; optical systems 12, 22 which shape and guide beams 15, 25 of the two types of lasers respectively so as to irradiate the surface of the substrate 30 therewith; and a moving device 3 which moves the substrate 30 relatively to the laser beams 15, 25 to allow scanning of the combined irradiation of the two types of laser beams. According to this apparatus, deep activation of impurities can be performed in a thick semiconductor substrate with large heat capacity while securing sufficient light penetration depth and thermal diffusion length therefor.

### TECHNICAL FIELD

The present invention relates to a laser annealing apparatus and a laser annealing method for use in activation of impurities ion-implanted to the reverse side of a power device IGBT (Insulated Gate Bipolar Transistor), a treatment for recovering crystals by removing crystal defects in a wafer surface layer, and the like.

### BACKGROUND ART

For the power device IGBT (Insulated Gate Bipolar Transistor), a unique reverse process (thin wafer process) is carried out. In a heat treatment performed after a surface process, in which the reverse side of a wafer is thinly ground, and impurities ion-implanted thereto is activated, a semiconductor substrate is irradiated with laser beams to heat the surface thereof, and the heat treatment is performed by means of this temperature rising.

In such a heat treatment, it is preferable to effectively heat the substrate up to a certain depth position thereof to enhance the activation. However, currently-used lasers can not sufficiently perform activation because a light penetration depth and heating time by the laser are short due to their short rise time and narrow pulse width (half-value width of pulse). Therefore, an activation method in which an apparent pulse width is extended by continuous irradiation with a plurality of pulses and a dual-wavelength laser activation method in which lasers differed in wavelength are combined to extend the light penetration depth have been proposed.

For example, an activation technique for operating CW (continuous wave) lasers of two wavelengths, that is, short wavelength and long wavelength, is proposed so that a shallow ion-implanted layer and a deep ion-implanted layer respectively are activated (refer to Patent Literature 1).

In this technique, the same substrate surface is irradiated simultaneously with a CW type LD (wavelength≦900 nm) and a harmonic laser of CW type YAG laser (wavelength≧370 nm), and the irradiation time (determined depending on beam scanning rate and beam size) of each laser beam is controlled to thereby control the temperature distribution in depth direction, whereby deep activation is attained. A shallow portion of an impurity-implanted layer is activated by a short-wavelength solid state laser, and a deep portion thereof is activated by a semiconductor laser.

A technique for activating a shallowly-implanted impurity layer in a melted state and a deeply-implanted impurity layer in a non-melted state by use of a double-pulsed laser annealing apparatus is also proposed (refer to Non-Patent Literatures 1, 2).

In the double-pulsed laser annealing apparatus according to this technique, for activation of a deep pn junction, two green pulse lasers are used, and a delay time is provided between the two laser pulses having 100 ns-level short pulse widths to extend the pulse width in a pseudo manner, whereby annealing time is gained. A shallow boron-implanted layer and a deep phosphor-implanted layer are collectively activated by optimizing the delay time. A high activation ratio is obtained therein with an activation depth reaching 1.8 μm. This activation of the pn junction is a stepwise process from solid phase to liquid phase, in which the deep phosphor-implanted layer is firstly recovered of the crystals in a solid phase state, and the shallow boron-implanted layer is then epitaxially grown in liquid phase with the recovered phosphor layer as a seed crystal.

Furthermore, a technique for activating an amorphous layer formed by ion implantation in a melted state by combining dual-wavelength lasers is also proposed (refer to Non-Patent Literature 3).

This technique is a melting activation method in which dual-wavelength lasers of an infrared wavelength of 1060 nm (pulse width 40 ns) and a green wavelength of 530 nm (pulse width 30 ns) are simultaneously emitted, whereby a surface of an amorphous layer (48 nm) implanted with As ion (30 keV, E+15/cm²) is shallowly melted by the green-wavelength pulse laser firstly to enhance absorption of infrared wavelength, and the entire amorphous layer is then melted by the infrared-wavelength pulse laser. The green pulse laser plays a trigger-like role for light absorption of the infrared pulse laser.

### CITATION LIST

### Patent Literature

Patent Literature: International Publication No. 2007/015388

### Non-Patent Literature

Non-Patent Literature 1: Toshio Kudo and Naoki Wakabayashi, “PN Junction Formation for High-Performance Insulated Gate Bipolar Transistors (IGBT): Double-Pulsed Green Laser Annealing Technique”, Mater Res. Soc. Symp. Proc., Material Research Society, Vol. 912, 2006
Non-Patent Literature 2: Toshio Kudo, “Double-Pulsed Solid State Laser Annealing Technologies: Application to Backside Activation Process for High Power Transistors”, Journal of Japan Laser Processing Society, Vol. 14, No. 1, 2007 May
Non-Patent Literature 3: D. H. Auston and J. A. Golovchenko, “Dual-wavelength laser annealing”, Appl. Phys. Lett., 34, (1979) 558.

### SUMMARY OF INVENTION

### Problems to be Solved by the Invention

As shown in Patent Literature 1, a combination of long-wavelength CW lasers allows effective use of penetration depth of long-wavelength light. However, in irradiation with 805-nm laser, for example, light penetration depth Lα is 10.7 μm at room temperature (300° K) and 2.1 μm at 1000° K, and is further reduced near the melting point. Even by such a long-wavelength laser irradiation, if accompanied with a rapid temperature rise, it becomes difficult to secure an activation temperature up to an intended deep region.

If the pulse width is extended in a pseudo manner by providing a delay time between two pulse lasers, as shown in Non-Patent Literatures 1, 2, sharp reduction in light penetration depth is unavoidable since light absorption by phonon is sharply increased in accordance with steep rise of the substrate surface temperature. In irradiation with 515-nm green laser, for example, the light penetration depth Lα is 0.79 μm at room temperature (300° K) and 0.16 μm at 1000° K, and is sharply reduced to about ⅕ by the temperature rise from room temperature to 1000° K. When the surface is melted particularly, the light penetration depth is extremely reduced to 8 nm, and the laser light is prevented from deeply penetrating causing a loss of irradiation, since the reflectance is sharply increased from 36% to 72% due to the melting of the surface. Therefore, achievement of the melting point in a short time by rapid temperature rise inhibits securement of the activation temperature up to an intended deep area.

Further, the light penetration depth can be extended by extending the wavelength of the laser being irradiated, as shown in Non-Patent Literature 3. On the other hand, in irradiation with 805-nm laser, for example, the light penetration depth Lα is 10.7 μm at room temperature (300° K) and 2.1 μm at 1000° K, and is sharply reduced to about ⅕ according to the rise of substrate surface temperature similarly to the case of the green laser. However, from the viewpoint of the light penetration depth, a long wavelength is more advantageous for the activation of a deep area than a short wavelength. When the activation is performed in a melted state, however, the reduction in the time to melting point by rapid temperature rise is also disadvantageous for the securement of the activation temperature to the deep area due to the extremely reduced light penetration depth of 8 nm and the loss of irradiation energy by the sharp increase in reflectance.

Further, the present inventors have confirmed that in use of pulse lasers, a marked difference in activation depth is shown between a thick silicon wafer (e.g., 725 μm) and a thin silicon wafer (e.g., 150 μm) which have different heat capacities. Namely, in the thick silicon wafer (e.g., 725 μm) with large heat capacity, deep activation exceeding 2 μm, for example, cannot be attained due to an insufficient activation temperature.

For low thermal budget (low-temperature) activation of the reverse side of the power device IGBT, it is important to secure a light penetration depth and a thermal diffusion length capable of covering an intended activation area, irrespective of the heat capacity of the substrate, and the related art cannot sufficiently respond to this.

The present invention is thus achieved in the context of the above-mentioned circumstances, and has an object to provide a laser annealing apparatus and a laser annealing method, capable of efficiently performing a heat treatment such as activation treatment of impurities while securing sufficient light penetration depth and thermal diffusion length therefore even in a thick silicon wafer with large heat capacity.

### Means for Solving by the Invention

A laser annealing apparatus according to the present invention is a laser annealing apparatus for heat-treating a substrate surface, comprising: a pulse oscillation laser source which generates a pulse laser with gentle rise time and long pulse width; a continuous wave laser source which generates a near-infrared laser for assisting annealing; an optical system which shapes and guides each beam of the two types of lasers so as to irradiate the substrate surface in a combined manner; and a moving device which moves the substrate relative to the laser beams to allow scanning of the irradiation of the two types of laser beams.

A laser annealing method according to the present invention is a laser annealing method for heat-treating a substrate surface, comprising: repetitively overlap-irradiating the substrate with a pulse laser beam with gentle rise time and long pulse width, which is generated by a pulse oscillation laser source and shaped, also irradiating the repetitively overlap-irradiated substrate with a near-infrared laser beam, which is generated by a continuous wave laser source and shaped, in a combined manner, and performing heat treatment of the substrate while scanning these laser beams, preferably while suppressing a temperature rise on the non-irradiated side of the substrate.

In the present invention, annealing treatment is performed by irradiating the substrate surface with the pulse laser beam with gentle rise time and long pulse width, which is generated by the pulse oscillation laser source and shaped, and the near-infrared laser beam which is generated by the continuous wave laser source and shaped in a combined manner. Since the near-infrared laser assists the annealing to secure sufficient thermal diffusion in depth direction, a heat treatment such as activation treatment of impurities can be efficiently performed even on a thick silicon wafer with large heat capacity or the like.

As the above-mentioned pulse laser, green laser can be suitably used, and as the pulse laser oscillator, for example, second harmonics of LD-excited Yb:YAG laser can be used.

The pulse laser in the present invention is emitted to the substrate while having a pulse waveform with gentle rise time, compared with general pulse lasers. Concretely, the pulse laser is preferably emitted to the substrate while having a pulse waveform with a rise time of the pulse waveform from 10% of maximum intensity to 90% thereof being 160 ns or more. The rise time is more preferably 180 ns or more, further more preferably 300 ns or more.

Such a pulse laser gentle in rise can suppress, when emitted to the substrate, a steep temperature rise of the substrate in an early stage of irradiation and reduce a steep reduction in light penetration depth associated with this temperature rise.

In the present invention, although the laser source for outputting the laser pulse gentle in rise is not limited to a specific one, those equipped with second harmonics of LD-excited Yb:YAG laser as described above can be given as a preferred example.

The above-mentioned laser pulse is required to have not only a gentle rise time but also a long pulse width. Concretely, the laser pulse is preferably emitted to the substrate while having a pulse waveform having a half-value width of 600 ns or more, further preferably 1000 ns or more.

A thermal diffusion length commensurate with the light penetration depth can be secured by controlling (extending) the pulse width of the pulse laser, whereby a low thermal budget process (low-temperature activation treatment) or the like can be effectively attained.

The near-infrared laser which is generated by the continuous wave laser source, for example, can have a wavelength of 650 to 1100 nm. Preferably, the wavelength is 680 to 825 nm. In the above-mentioned wavelength band, a light penetration depth larger than that in the above-mentioned pulse laser can be obtained due to satisfactory light absorption to silicon that is a general material used for the substrate. As a result, the substrate is preheated up to the deep area, and the assisting action is effectively obtained.

The above-mentioned near-infrared laser may partially include a discontinuous portion in which the power density is minimized, besides continuous-waveform ones just generated by the continuous wave laser source. This discontinuous portion preferably emerges in the same period as the pulse of the pulse laser. The discontinuous portion may have a zero power density, besides a power density smaller than in a continuous portion. The discontinuous portion functions to adjust a heating value being given to the substrate to thereby prevent the whole substrate from being excessively heated. The discontinuous portion is preferably set to 50% or less relative to one period of the pulse laser. The discontinuous portion can be provided by means of current control of semiconductor laser or the like.

The assist temperature by the near-infrared laser is preferably adjusted so as not to exceed a material melting point of the substrate surface. This adjustment can be performed, for example, by controlling the power density of the near-infrared laser and the scanning rate.

In the present invention, escape of heat is moderated (minimized) by the above-mentioned combined irradiation of pulse laser beam and near-infrared laser beam to raise the activation temperature, whereby the heat treatment of the substrate can be performed while suppressing the temperature rise on the non-irradiation side of the substrate.

The timing of the irradiation is preferably controlled by providing a delay time so that the substrate can be irradiated with the pulse laser beam when the substrate surface temperature reaches a steady state after the irradiation with the near-infrared laser. The temperature assist can be effectively utilized by irradiating the substrate surface with the pulse laser beam after the substrate surface temperature reaches the steady state by the irradiation with the near-infrared laser beam.

In the present invention, the relationship between the irradiation position of the pulse laser beam and the irradiation position of the near-infrared laser is never limited to a specific one as long as an annealing assisting action by the near-infrared laser can be secured. Therefore, the near-infrared laser beam and the pulse laser beams may be emitted so that the respective irradiation areas are partially or entirely overlapped with each other on the substrate surface, or each of the beams may be emitted with a position gap without overlap of the both.

The irradiation area can be shown as an area on the substrate surface where the energy density of the pulse laser beam or the power density of the near-infrared laser beam is, for example, 90% or more.

However, for effectively developing the assisting action, the irradiation area of the near-infrared laser beam is preferably set to be larger than the irradiation area of the pulse laser beam, and the irradiation area of the near-infrared laser beam is more preferably set so as to cover the irradiation area of the pulse laser beam. For obtaining an action as preheating, it is preferred that part or all of the irradiation area of the near-infrared laser beam is located beyond the irradiation area of the pulse laser beam at least on the scanning direction side and, further, for obtaining an action as after-heating or the like, it is further more preferred that the irradiation area of the near-infrared laser beam is extended beyond the irradiation area of the pulse laser beam on the opposite side in the scanning direction. The positional relationship of irradiation area between both the laser beams is preferably symmetric to a direction orthogonal to the scanning direction. According to this, the same relationship can be obtained when the scanning direction is inverted.

Namely, the irradiation area of the near-infrared laser beam preferably has a size to extend beyond the whole irradiation area of the pulse laser beam. By securing an irradiation area of near-infrared laser beam wider than the irradiation area of pulse laser beam, lateral escape of heat in the substrate can be moderated, contributing to increase in activation temperature.

In the above case, the size (cross-sectional size) of the near-infrared laser beam must be larger than the size (cross-sectional size) of the pulse laser beam. In this case, the beam size of the near-infrared laser is preferably at least the beam size of the pulse laser+the maximum thermal diffusion length (300° K). The maximum beam size of the near-infrared laser can be determined depending on whether the assist temperature determined by the power density and the scanning rate of the substrate is sufficient for the deep activation or not. The assist temperature must be set to be lower than the melting point of a material (generally, silicon) on the substrate surface as described above.

The above-mentioned pulse laser beam irradiation and near-infrared laser beam irradiation are preferably performed on the substrate around at the same time. Therefore, both the beams may be emitted simultaneously to a predetermined position of the substrate or may be emitted to the predetermined position of the substrate with a time lag. When the time lag is provided, the time lag is set so that the assisting action by the near-infrared laser beam can be effectively obtained in the pulse laser beam irradiation. Namely, when the time lag is set to be excessively large, the assisting action by the near-infrared laser beam cannot be sufficiently obtained in the pulse laser beam irradiation. The above-mentioned irradiation with a time lag while preserving the assisting action is also included in the above-mentioned irradiation around at the same time.

The above-mentioned beam size or relationship of irradiation position can be adjusted by an optical system. The optical system includes optical materials such as a homogenizer, a lens and a mirror to perform shaping or deflection of a laser beam or like.

In the present invention, the temperature rise of the non-irradiation surface opposite to the laser irradiation surface can be suppressed by minimizing the temperature gradient. In that case, the temperature rise of the non-irradiation substrate surface opposed to the laser irradiation surface is preferably suppressed to 200° C. or lower, further preferably to 100° C. or lower.

### Advantages of the Invention

Namely, the present invention has the following effects.

1) By imparting a near-infrared laser beam as temperature assist to a pulse laser beam, impurities ion-implanted to a thick silicon substrate with large heat capacity can be sufficiently activated to a deep position.

2) By imparting the near-infrared laser beam as temperature assist to the pulse laser beam, the thermal load of the pulse laser can be reduced, the energy density necessary for the activation can be reduced to extend the beam length, and a large sweep rate of irradiation can be thus secured. Therefore, the throughput can be improved.

3) Since preheating can be performed to a deep area, potentially deep activation beyond 3 μm can be attained.

4) A sub-role as temperature assist is assigned to the near-infrared laser while putting the pulse laser in a main role in the heat treatment, whereby the temperature rise on the non-irradiation side of the substrate can be suppressed to, for example, 200° C. or lower. A discontinuous portion may be provided in part of the near-infrared laser, whereby the temperature rise on the non-irradiation side of the substrate can be further improved.

### BRIEF DESCRIPTION OF THE DRAWINGS

FIG. 1 is a schematic view showing a laser annealing apparatus according to one embodiment of the present invention.

FIG. 2 are schematic views showing an irradiation area of pulse laser beam and an irradiation area of near-infrared laser beam on a substrate surface.

FIG. 3 are schematic views showing one example of a cross-section structure of a power device IGBT that is an example of an irradiation object.

FIG. 4 is a pattern diagram of laser pulse waveforms having contrast rise times of the embodiment of the present invention and a conventional case.

FIG. 5 is a view showing pulse waveforms of LD-excited solid state lasers.

FIG. 6 is a view showing time changes of substrate temperature by irradiation with a steep-rise pulse laser and by irradiation with a slow-rise pulse laser.

FIG. 7 is a view showing effects of the rise time in pulse waveform on the average light penetration depth.

FIG. 8 is a view showing timings of irradiation of near-infrared laser beam and pulse laser beam.

FIG. 9 is a view showing a modified example of the timings of irradiation of near-infrared laser beam and pulse laser beam.

FIG. 10 are pattern diagrams showing thermal diffusions in substrate depth direction by laser beam irradiation in an embodiment of the present invention and in a reference example.

FIG. 11 is a schematic view showing irradiation areas of near-infrared laser beam and pulse laser beam on a substrate in an example of the present invention.

FIG. 12 is a view showing profiles of carrier concentration distribution in depth direction by irradiation with combined laser beams in an example of the present invention.

FIG. 13 is a view showing profiles of carrier concentration distribution in depth direction by irradiation with single pulse laser beam in a comparative example.

### EMBODIMENT OF THE INVENTION

A preferred embodiment of the present invention will be then described.

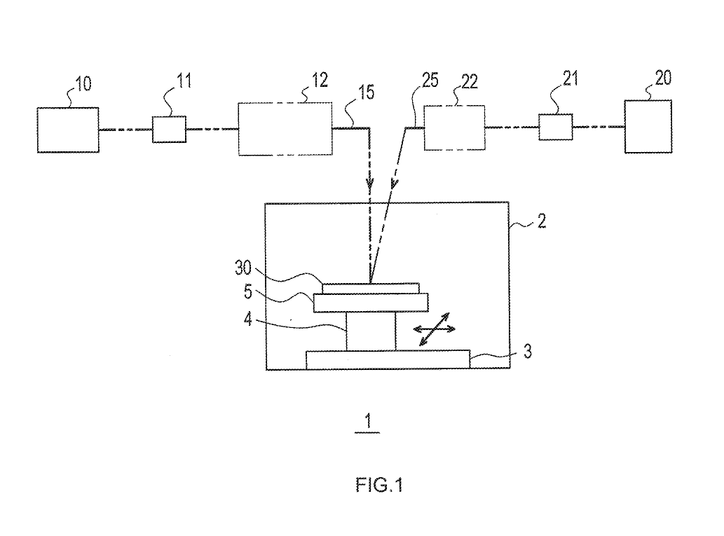

A laser annealing apparatus 1 comprises, as shown in FIG. 1, a treatment chamber 2; a moving device 3 movable in X-Y directions, which is provided inside the treatment chamber 2; and a base 4 provided on an upper portion of the moving device 3. A treatment object placement table 5 is provided on the base 4. A semiconductor substrate 30 is placed on the treatment object placement table 5 in laser annealing treatment. The moving device 3 is driven by a motor not shown or the like.

A pulse oscillation laser source 10 equipped with second harmonics of LD-excited Yb:YAG laser is installed outside the treatment chamber 2. A pulse laser beam 15 output from the pulse oscillation laser source 10 is adjusted in energy density by an attenuator 11 as needed, subjected to beam shaping or deflection by an optical system 12 constituted by a lens, a reflection mirror, a homogenizer and the like, and emitted toward the semiconductor substrate 30 in the treatment chamber 2.

The pulse laser beam 15 output from the pulse oscillation laser source 10 has a pulse waveform with gentle rise time, preferably a pulse waveform having a rise time (the time for the pulse waveform to rise from 10% of maximum intensity to 90% thereof) of 160 ns or more and a half-value width of 200 ns or more. This laser beam is preferably adjusted to an energy density for maintaining an impurity layer in a non-melted state such that when the semiconductor substrate 30 is irradiated therewith, the temperature of a surface layer can be raised to a high temperature around the melting point, or a state where only the surface layer is melted can be obtained. The pulse laser beam 15 is shaped to, for example, a line beam shape by the optical system 12 as described above.

A continuous wave laser source 20 composed of an LD laser source which generates a near-infrared laser is installed outside the treatment chamber 2. A near-infrared laser beam 25 output from the continuous wave laser source 20 is adjusted in power density by an attenuator 21 as needed, subjected to beam shaping or deflection by an optical system 22 constituted by a lens, a reflection mirror, a homogenizer and the like, and emitted to the semiconductor substrate 30 in the treatment chamber 2. This laser beam is adjusted to a power density such that when the semiconductor substrate 30 is irradiated and scanned, the semiconductor substrate 30 does not reach the melting point. The near-infrared laser beam 25 is shaped to, for example, a line beam shape by the optical system 22, as described above, and the size thereof is adjusted so as to be larger than the size of the pulse laser beam 15.

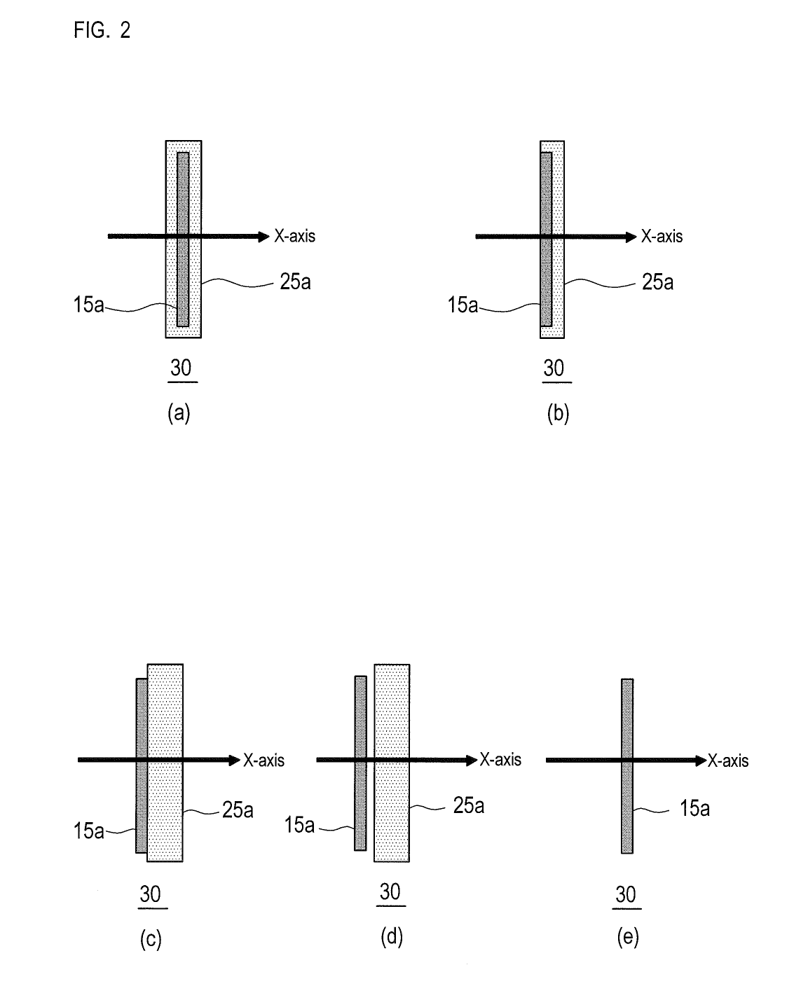

As shown in FIG. 2(a), an irradiation area 25a in the irradiation of the semiconductor substrate 30 with the near-infrared laser beam 25 is adjusted by the optical systems 12, 22 so as to have a size to cover an irradiation area 15a in irradiation of the semiconductor substrate 30 with the pulse laser beam 15 and also to extend beyond the entire area of the pulse laser beam 15.

In the present invention, the position of the irradiation area of each laser beam is never limited to the above. FIGS. 2(b), 2(c), 2(d) show modified examples of the position of the irradiation area. In FIG. 2(b), the irradiation area 25a has a size larger than the irradiation area 15a in the longitudinal direction and scanning direction. In FIG. 2(c), the irradiation area 25a is located on the scanning direction side of the irradiation area 15a without covering the irradiation area 15a or without overlap of the both, and the edges of the adjacent irradiation areas are in contact with each other. In FIG. 2(d), the irradiation area 25a is separated from the irradiation area 15a without covering the irradiation area 15a or without overlap of the both. However, the both are emitted adjacently to each other on the substrate.

In FIG. 2(e) which shows an irradiation state out of the present invention, the semiconductor substrate 30 is irradiated with only the pulse laser beam 15, and treated by the irradiation area 15a.

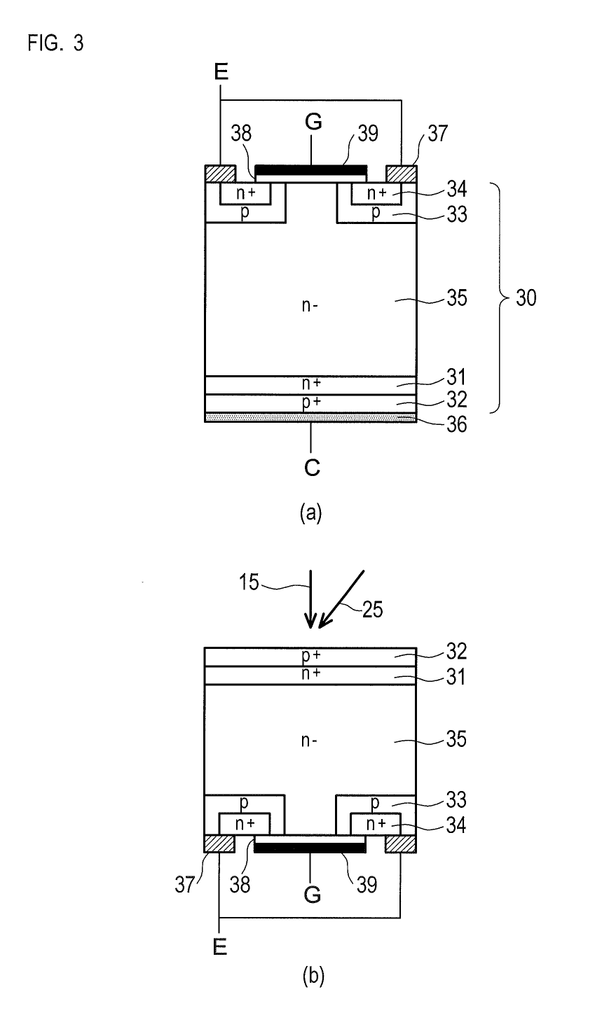

FIG. 3(a) shows a cross⁻section structure of an example of an FS type IGBT which can be taken as a treatment object in the present invention. A boron-implanted p-type base area 33 is formed on the surface side of a semiconductor substrate 30, and a phosphor-implanted n+ type emitter area 34 is formed in a part of the surface side of the p-type base area 33. A boron-implanted p+ type collector layer 32 is formed on a surface layer on the reverse side of the semiconductor substrate 30. A phosphor-implanted n+ type buffer layer 31 is formed in an area deeper than the collector layer 32 so as to contact with the collector layer 32, and an n− type substrate 35 is located on the inner side thereof. In the drawing, denoted by 36 is a collector electrode, 37 is an emitter electrode, 38 is a gate oxide film, and 39 is a gate electrode.

The above-mentioned semiconductor impurity layers are activated by the repetitive overlap-irradiation of the pulse laser beam 15 with the continuous irradiation of the near-infrared laser beam 25 around at the same time from the reverse side prior to the formation of the collector electrode 36 as shown in FIG. 3(b), whereby the impurity layers are activated over a thickness of 2 μm or more. An overlap ratio of the pulse laser beam 15 can be appropriately selected as needed. In that case, the moving speed of the base 4 by the moving device 3 is controlled, whereby the pulse laser beam 15 and the near-infrared laser beam 25 can be scanned at a predetermined speed on the semiconductor substrate 30.

How the present invention can attain the activation of an intended deep area while effectively using the light penetration depth originating from the wavelength of pulse laser will be then described.

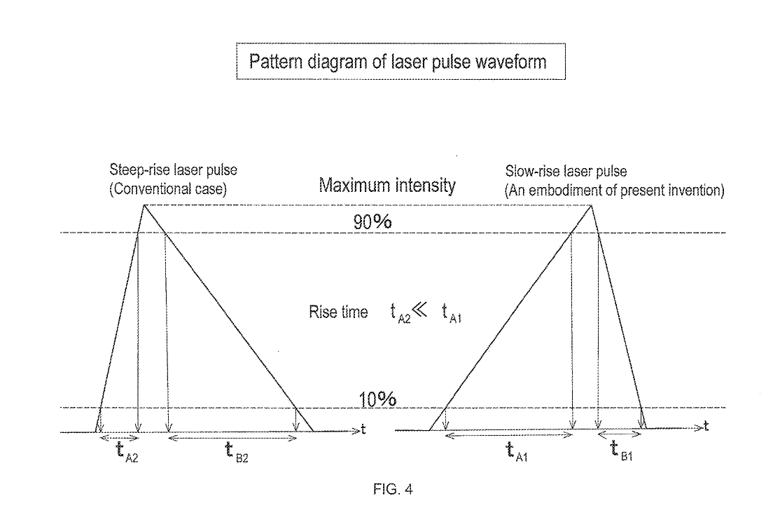

In FIG. 4, the pulse waveforms of pulse lasers in a conventional case and in an embodiment of the present invention are shown as a pattern diagram. The rise time of pulse waveform from 10% of maximum intensity to 90% thereof is defined as t_{A}, and the fall time from 90% of maximum intensity to 10% is defined as t_{B}. The conventional pulse laser has an asymmetric pulse waveform having a short rise time t_{A2} and a long fall time t_{B2}. In contrast, the pulse laser in the embodiment of the present has an asymmetric pulse waveform opposite to the conventional one, which has a long rise time t_{A1} and preferably has a short fall time t_{B1}. In comparison of the rise time, an embodiment of the prevent invention is characterized by that the rise time is much longer than that in the conventional case.

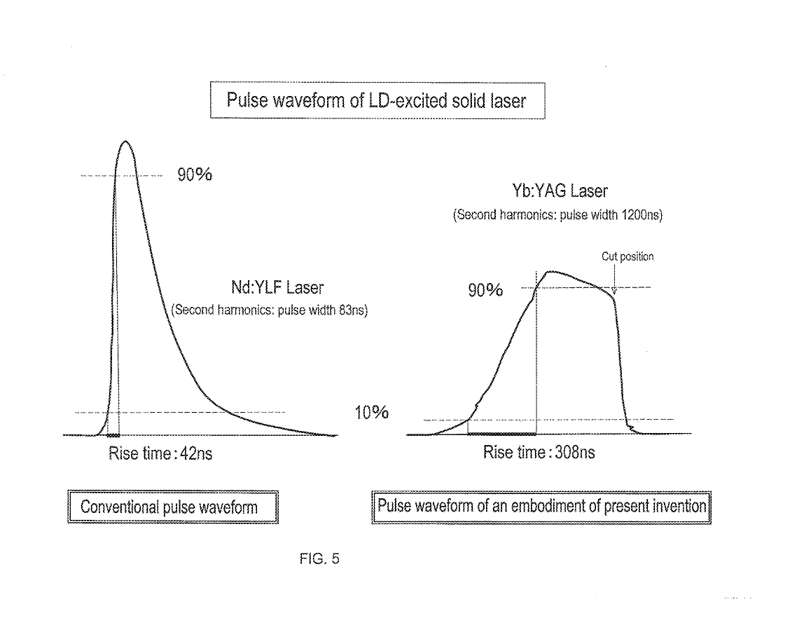

FIG. 5 concretely shows the pulse waveforms of second harmonics of LD-excited solid state lasers in a conventional case and in an embodiment of the present invention. In the conventional case, the pulse waveform has a rise time of 42 ns and a fall time of 120 ns relative to a pulse width (half-value width) of 83 ns.

The pulse waveform in the embodiment of the present invention has a rise time of 308 ns and a fall time of 92 ns relative to a pulse width (half-value width) of 1200 ns.

The pulse laser in the embodiment of the present invention apparently has a gentle rise time and a long pulse width, compared with that in the conventional case.

In an embodiment of the present invention, as the degree of asymmetry of pulse waveform, the symmetry of pulse waveform or a value obtained by dividing the rise time by the fall time can be taken as an indication. Symmetry of pulse waveform smaller than 1 means steep rise and slow fall, while symmetry larger than 1 means slow rise and steep fall. In the second harmonics of Nd:YLF or Nd:YAG of the conventional case, the symmetry of pulse waveform is smaller than 1. In the second harmonics of Yb:YAG in the embodiment of the present invention, the symmetry of pulse waveform is larger than 2.

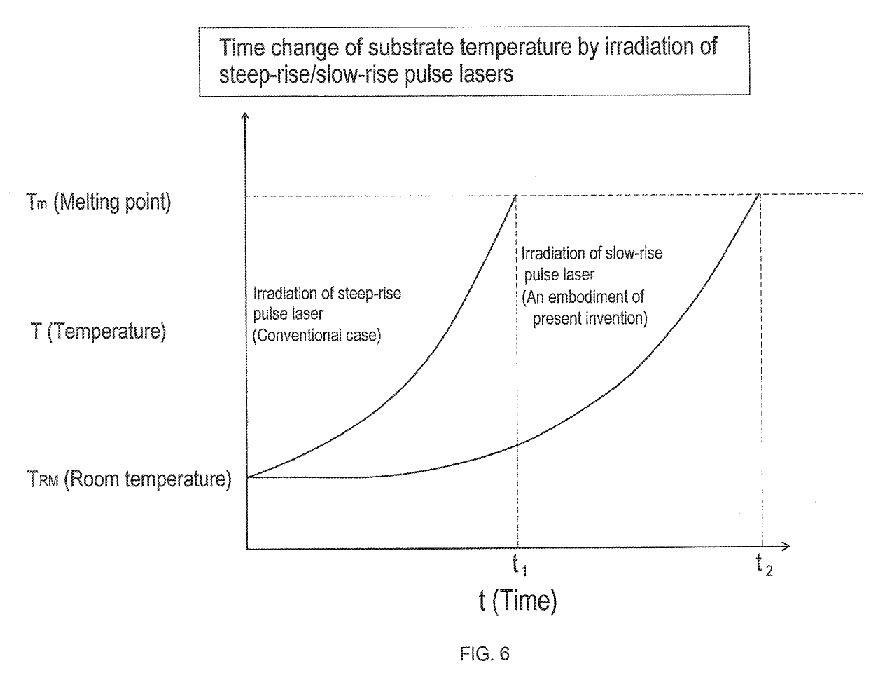

FIG. 6 is a pattern diagram of the progress of wafer surface temperature rise in irradiation of a silicon wafer, that is, a substrate by use of the above-mentioned pulse lasers. As an indication of the rise time of pulse waveform in the pulse lasers, the time to melting from room temperature can be introduced. In the use of the conventional pulse laser, the substrate temperature sharply rises and early reaches the melting point, while the rise of substrate temperature is slow, in the use of the pulse laser in an embodiment of the present invention, and the time to the melting point is also extended. In the heat treatment of an embodiment of the present invention, the treatment may be performed without the substrate surface reaching the melting point, or the melting may be caused in the middle of the treatment. Even in the case where the melting is caused, the time to the melting can be extended, and a sufficient penetration depth of laser beam can be secured.

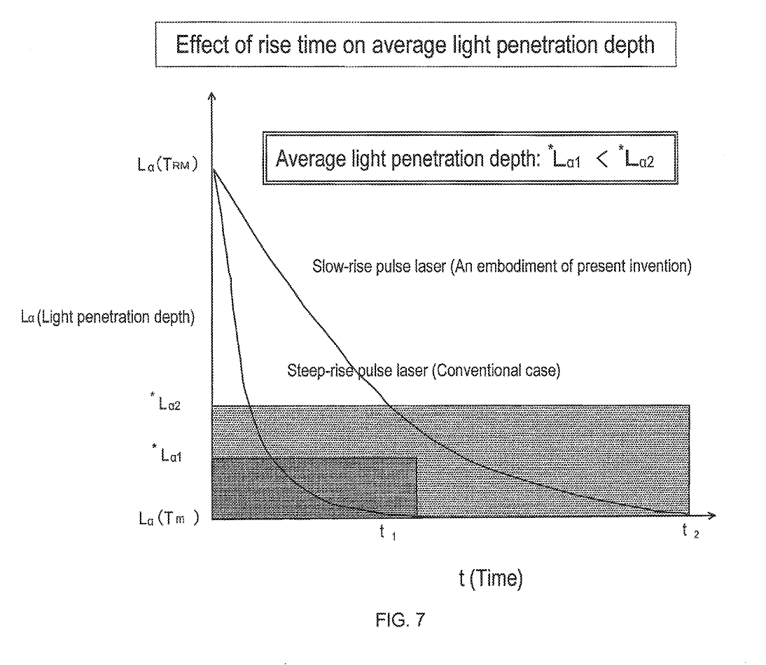

FIG. 7 is a pattern diagram of temperature changes of the light penetration depth to a silicon wafer of a conventional pulse laser and the pulse laser in an embodiment of the present invention. The light penetration depth La is defined as an inverse of linear absorption coefficient α. The linear absorption coefficient of the silicon wafer is represented by equation (1), depending on temperature.

α(T)=α₀exp(T/T_{R}) (1)

wherein each of α₀ and T_{R} is a constant depending on wavelength (refer to Reference Literature 1).

The equation (1) satisfactorily agrees with experimental results in a temperature range of 300° K≦T≦1000° K and a wavelength range of λ<410 nm. In the drawing, Lα(T_{RM}) represents a light penetration depth at room temperature, and Lα(Tₘ) represents a light penetration depth at melting point.

### REFERENCE LITERATURE 1

Authors: G. E. Jellison and F. A. Modine

Literature Title: Optical functions of silicon between 1.7 and 4.7 eV at elevated temperature

Published Magazine; Phys. Rev. B27, p 7466

Publication Date: 1983

For examining effects of the rise time of pulse waveform on the light penetration depth, a time average of light penetration depth is introduced. In FIG. 7, time averages Lai and Lae of penetration depth in irradiation of pulse lasers having contrast rise times of a conventional case and an embodiment of the present invention are shown. The time average *Lα of light penetration depth can be calculated from each rectangle shown in the drawing, the rectangle having the same area as that obtained by integrating Lα-t graph up to time 0 to t₁, or 0 to t₂. When the rise time is extended as in the pulse laser of the embodiment of the present invention, the area calculated from the Lα-t graph is enlarged, and the average light penetration depth is increased, compared with the conventional case with short rise time. Therefore, deep activation can be more effectively performed when the pulse waveform rise time of pulse laser is longer.

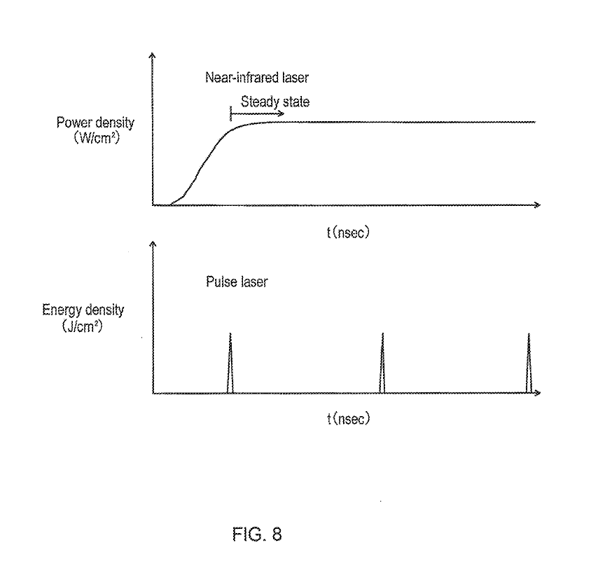

In FIG. 8, the timing of the irradiation with near-infrared laser which is performed around at the same time as the irradiation with the above-mentioned pulse laser is shown.

On a substrate surface irradiated with the near-infrared laser, the temperature gradually rises just after the irradiation and gets into a steady state. On the other hand, in the irradiation with the pulse laser, the temperature rises extremely rapidly according to the pulse, and also falls extremely rapidly according to the pulse. The irradiation with the pulse laser is preferably performed after the substrate surface temperature reaches the steady state by the irradiation with the near-infrared laser. As the timing of irradiation, for example, a delay time is preliminarily set, and the pulse laser is emitted with a time lag according to the delay time after the irradiation with the near-infrared laser beam. Otherwise, the timing of irradiation can be changed by scanning the combined laser beams with a position gap so that the respective irradiation areas are not overlapped.

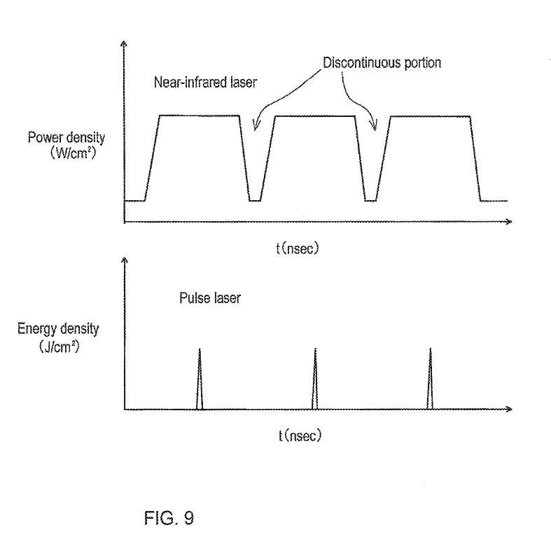

In an embodiment of the present invention, the near-infrared laser may partially include a discontinuous portion, as shown in FIG. 9, without being limited to a continuous waveform.

The discontinuous portion preferably emerges in the same period as the pulse of the laser beam.

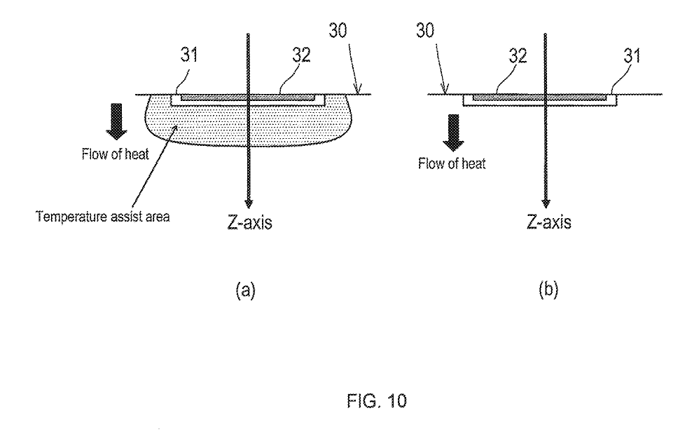

A pattern diagram of thermal diffusion in depth direction in irradiation of a semiconductor substrate with the above-mentioned pulse laser and near-infrared laser beam is shown in FIG. 10(a).

A semiconductor substrate 30 has a boron-implanted area 32 and a phosphor-implanted area 31, and a temperature assist area is formed to a deep position of the semiconductor substrate 30 by irradiation with the near-infrared laser beam larger in light penetration depth than the pulse laser. For example, a near-infrared laser beam having a wavelength of 808 nm can provide a light penetration depth of about 10 μm in the depth direction. When the semiconductor substrate is irradiated with the pulse laser beam in this state, a flow of heat is generated in the depth direction (Z-axial direction). The temperature assist area minimizes the gradient of heat, and the escape of heat is consequently minimized to allow effective heating of the semiconductor substrate to a deep portion. In that case, the activation of impurities can be performed in a non-melted state or in a state where only the surface is melted, with suppressing the temperature rise on the non-irradiation side of the semiconductor substrate by adjustment of the energy density of the pulse laser, the power density of the near-infrared laser or the scanning rate.

FIG. 10(b) shows a state where the semiconductor substrate 30 is irradiated with only the pulse laser. In this case, the temperature gradients in the surface direction and depth direction are large, and the escape of heat is increased. Therefore, the heating effect in the depth direction is limited, and the activation of impurities to a deep position can hardly be performed on a thick semiconductor substrate with large heat capacity.

### EXAMPLE 1

An example of the present invention will be then described.

As the green pulse laser, second harmonics of LD-excited solid state laser (DPSS) were used, and as the pulse oscillation laser source, LD-excited Yb:YAG was used. A pulse laser beam (wavelength 515 nm) being output from the laser source and emitted to a semiconductor substrate was set to have a pulse width of 1200 ns, a rise time of 308 ns, a fall time of 92 ns, an energy density of 8 J/cm², and a pulse frequency of 10 kHz, and the substrate was repeatedly overlap-irradiated therewith from directly above.

On the other hand, the substrate was continuously irradiated with a near-infrared laser beam having a wavelength of 808 nm, which was generated by a continuous wave laser source, in a power density of 11.3 kW/cm²·sec and at an angle of 45° to the substrate. These beams were emitted to the semiconductor substrate around at the same time, and shaped respectively by optical systems so that the size (short axis 400 μm, long axis 560 μm) of the near-infrared laser beam was larger than the size (short axis 36 μm, long axis 300 μm) of the pulse laser beam, and so that the irradiation area of the near-infrared laser beam had an elliptic beam shape on the semiconductor substrate, while the irradiation area of the pulse laser beam had a slender elliptic beam shape having a size such that the near-infrared laser beam covered and extended beyond the entire irradiation area of the pulse laser beam. Each of the optical systems includes a long-axis cylindrical lens, a short-axis cylindrical lens, a spherical lens, a reflection mirror and the like, and can set the sizes of short axis and long axis of the beam by the constitution of the cylindrical lenses.

As the semiconductor substrate, a silicon substrate 725 μm in thickness was used, and the substrate was placed on the treatment object placement table on the base, and scanned at a rate of 80 mm/sec. by the moving device.

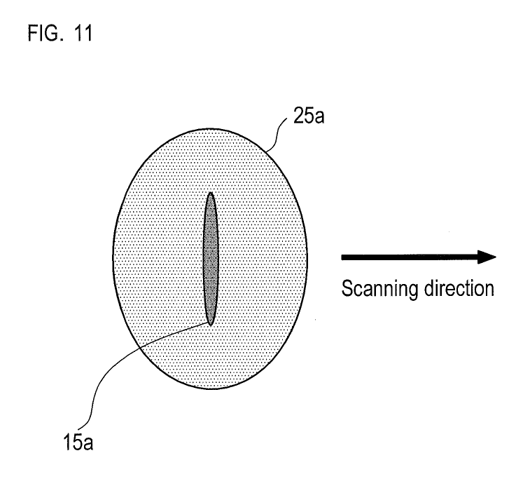

FIG. 11 shows irradiation areas 15a, 25a on the semiconductor substrate 30 of the pulse laser beam 15 and the near-infrared pulse laser 25 respectively. The irradiation area 25a has a size to cover and extend beyond the entire irradiation area 15a.

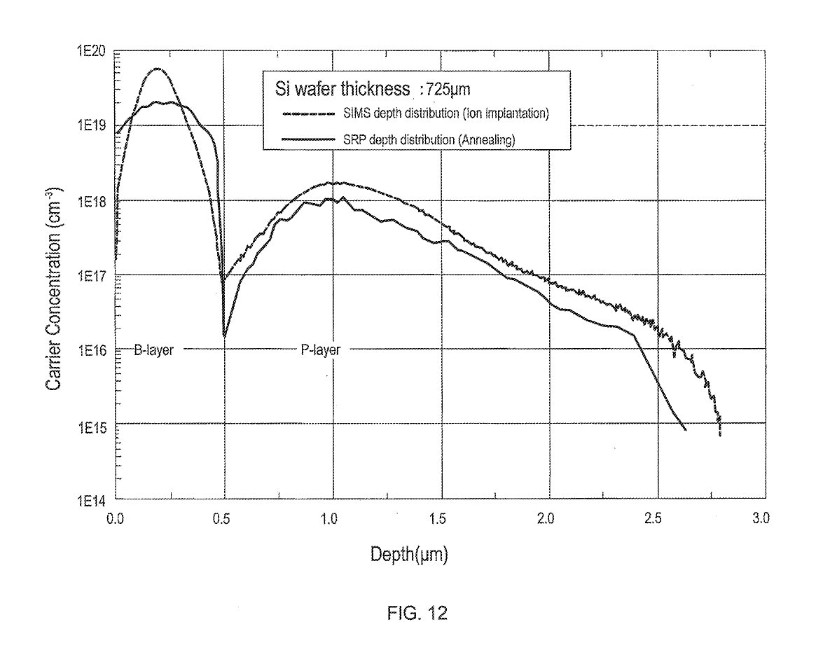

The semiconductor substrate was heat-treated by the irradiation with both the laser beams, and the depth distribution of impurity concentration by SIMS analysis in the semiconductor substrate before heat treatment was compared with the depth distribution of carrier concentration by SRP analysis in the semiconductor substrate after heat treatment to evaluate the activation depth, and the results were shown in FIG. 12.

As is apparent from FIG. 12, in the semiconductor substrate subjected to the irradiation of an example of the present invention, the activation treatment could be effectively performed up to a depth beyond 2 μm, in spite of its thickness as large as 725 μm.

A semiconductor substrate 150 μm in thickness was irradiated with both the laser beams in the same irradiation conditions as the above, and the temperature on the non-irradiation side thereof was measured. As a result, the measurement temperature was 200° C. or lower, and it is estimated from this result that the temperature on the non-irradiation side of the semiconductor substrate 725 μm in thickness which has a large heat capacity is 200° C. or lower also in the above-mentioned test example.

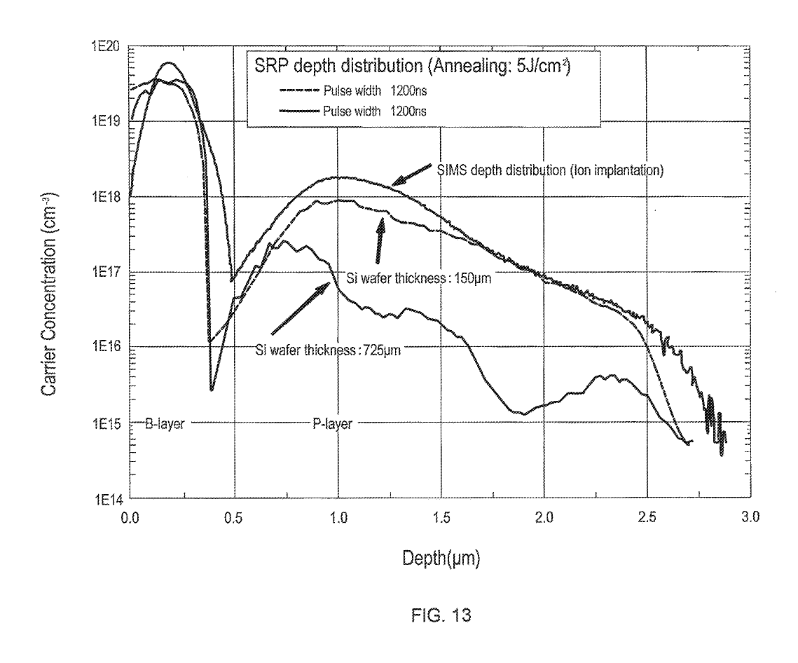

On the other hand, as a comparative example, using only the same pulse laser as the above without the near-infrared laser, heat treatment was performed on semiconductor substrates 150 μm in thickness and 725 μm in thickness by repeatedly overlap-emitting the pulse laser from directly above. The depth distributions of impurity concentration by SIMS of the semiconductor substrates before treatment and the depth distributions of carrier concentration by SRP of the semiconductor substrates after heat treatment were measured, and results thereof were shown in FIG. 13.

In this example, as is apparent from the drawing, deep activation beyond 2 μm could be attained in the semiconductor substrate 150 μm in thickness but not in the thick silicon wafer with large heat capacity (725 μm) due to an insufficient activation temperature.

### DESCRIPTION OF SYMBOLS

1 Laser annealing apparatus
2 Treatment chamber
3 Moving device
4 Base
5 Treatment object placement table
10 Pulse oscillation laser source
11 Attenuator
12 Optical system
15 Pulse laser beam
15a Irradiation area
20 Continuous wave laser source
21 Attenuator
22 Optical system
25 Near-infrared laser beam
25a Irradiation area
30 Semiconductor substrate

1-10. (canceled)

11. A laser annealing method for heat-treating a substrate surface, comprising:
repeatedly overlap-irradiating the substrate with a pulse laser beam having a pulse waveform with a rise time (the time for the pulse waveform to rise from 10% of maximum intensity to 90% thereof) of 160 ns or more and a half-value width of 600 ns or more, which is generated by a pulse oscillation laser source and shaped, also combination-irradiating the substrate subjected to the repeated overlap irradiation with a near-infrared laser beam, which is generated by a continuous wave laser source and shaped, and performing heat treatment of the substrate while scanning these laser beams.

12. The laser annealing method according to claim 11, wherein the pulse laser beam is obtained by cutting a pulse with a long pulse width in a pulse width direction to thereby shape it into an asymmetric pulse waveform in which the rise time is longer than a fall time to fall from 90% of the pulse intensity at a cut position to 10% thereof.

13. The laser annealing method according to claim 11, wherein the near-infrared laser beam and the pulse laser beam are emitted to the substrate so that the irradiation areas of both the near-infrared laser beam and the pulse laser beam are partially or entirely overlapped with each other on the substrate surface, or emitted with a position gap without overlap of the respective irradiation areas.

14. The laser annealing method according to claim 11, wherein the near-infrared laser beam and the pulse laser beam are emitted to the substrate so that an irradiation area of the near-infrared laser beam is larger than an irradiation area of the pulse laser beam on the substrate surface.

15. The laser annealing method according to claim 13, wherein a part or entire of the irradiation area of the near-infrared laser beam is located on the substrate surface beyond the irradiation area of the pulse laser beam at least on a scanning direction side

16. The laser annealing method according to claim 11, wherein the irradiation with the pulse laser beam and the near-infrared laser beam is performed so that a state where a surface layer of the substrate is not melted or only the surface layer is melted is maintained.

17. The laser annealing method according to claim 11, wherein the irradiation with the pulse laser beam and the near-infrared laser beam is performed while suppressing a temperature rise on the reverse side of the substrate opposed to the laser irradiation surface to 200° C. or lower.

18. The laser annealing method according to claim 11, wherein the near-infrared laser beam includes discontinuous portion at which a power density is minimized so as to adjust a heat quantity being given to the substrate.

19-20. (canceled)

21. The laser annealing method according to claim 14, wherein a part or entire of the irradiation area of the near-infrared laser beam is located on the substrate surface beyond the irradiation area of the pulse laser beam at least on a scanning direction side.
